(19) United States
(12) Patent Application Publication
(10) Pub. No.: US 2017/0178991 A1
(43) Pub. Date: Jun. 22, 2017

(54) METHOD FOR PRODUCING ELECTRONIC DEVICES

(71) Applicant: GEMALTO SA, Meudon (FR)

(72) Inventors: Stéphane OTTOBON, Gemenos Cedex (FR); Lucile DOSSETTO, Gemenos Cedex (FR); Lauren AUDOUARD, Gemenos Cedex (FR); Sébastien GUIJARRO, Gemenos Cedex (FR)

(73) Assignee: GEMALTO SA, Meudon (FR)

(21) Appl. No.: 15/036,641

(22) PCT Filed: Nov. 13, 2014
(86) PCT No.: PCT/EP2014/074541

§ 371 Date: May 13, 2016

(30) Foreign Application Priority Data
Nov. 19, 2013 (EP) 13306583.9

(51) Int. Cl. H01L 23/31; H01L 23/00; H01L 21/56

(52) U.S. Cl. CPC H01L 23/3121; H01L 21/561; H01L 21/563; H01L 21/568; H01L 24/97; H01L 24/49; H01L 23/562; H01L 2224/48091; H01L 2224/73265

(57) ABSTRACT

The invention relates to a method for producing an electronic device including at least one electronic component in a substrate body, said method including at least one step of transferring said electronic component to a surface of a removable dielectric substrate, of delivering a protective resin on said electronic component, and of transferring, onto the protective resin, a reinforcement disc having a main front surface with a peripheral contour, wherein the protective resin extends up to the peripheral contour of the disc in order to form, together with the disc, the peripheral side contours and the final layer of the substrate body of the device.

### FIELD OF THE INVENTION

The invention relates to an electronic device comprising at least one electronic component electrically connected to a communication interface.

The invention more particularly relates to a method for producing such an electronic device and the electronic device obtained. The invention further relates to a substrate for packaging a plurality of electronic devices thus produced.

Such electronic devices can be found in the form of cards, for instance, with various form factors such as small electronic objects in the micro-SD (the English acronym for “Secure Digital”), Micro-SIM (the English acronym for “Subscriber Identity Module”) or Plug-in SIM, Mini UICC (the English acronym for “Universal Integrated Circuit Card”) formats. Additionally, a whole range of devices can be found in the form of packages, enabling the surface mounting of components (indicated as CMS in French or SMD in English for “Surface Mounted Device”) as well as BGA (the English acronym for “Ball Grid Array”) type packages comprising connection balls. Such packages comprise a power supply and/or communication interface including electrical contacts or an antenna.

The invention more particularly, but not restrictively, relates to the production of secure portable electronic devices such as microprocessor cards or modules which can be applied specifically in the fields of health, banking, telecommunications or identity checks, physical access control and/or logic.

### PRIOR ART

Known techniques for making such objects require a sometimes slow, complex and not very adaptable process. An electronic module must generally be produced first, which is then inserted into the body of a package in order to form the electronic device. The production of an electronic device comprising at least one integrated circuit chip and/or one electronic component, mainly comprises the following steps:

defining a specific printed circuit coil;

mechanically cutting said printed circuit or

chemical etching in order to define a form of contacts;

cutting in a dielectric to create connection

wells;

laminating the dielectric onto the printed

circuit;

metallizing the contact pads;

bonding one or more chips having a various

thickness;

wiring for interconnecting said chips with the

contact pads;

coating the chip(s) and connections with a

protective resin,

laminating an adhesive onto the strip of thus

produced modules, then cutting and inserting each module into a package body so as to form an electronic device.

Document EP 1 780 662 further discloses the possibility of embedding the chip and the connections thereof in a mold wherein a reinforcement disc has been placed prior to the step of molding the coating resin. Such reinforcement disc makes it possible to mechanically protect the electronic module.

The electronic module thus formed is then inserted into the body of a package in order to form an electronic device. For this purpose, the module is transferred into a cavity provided in the package body. An alternative solution consists in placing the module on the bottom of a mold wherein the material composing the package body is over-molded in the final format of the electronic device.

A final step then consists in separating the molded or over-molded cases, by cutting using any type of cutting method (mechanical sawing, punching, laser, water jet).

Document FR 2 833 736 further discloses a method for over-molding a package on a removable paper substrate. Once the package is over-molded, a subsequent step consists in machining a cavity into the package in order to transfer therein an electronic module and thereby obtain a microprocessor card. The microprocessor card thus obtained is then separated from its detachable paper substrate.

The existing methods therefore require numerous steps which participate in high production costs.

In addition, in order to enable a better integration into portable devices such as telephones for example, the requirements, as regards reduced thickness and overall size of the electronic devices, are higher and higher. For example, the nano-SIM card, also indicated by the 4FF initials, the thickness of which is normalized to 0.67 mm, must thus have a thickness reduced by 11% relative to the micro-SIM card, indicated by the 3FF initials. This is the reason why it also becomes important to find solutions to optimize production methods, in order to take such requirements into account and enable the production of electronic devices with reduced thickness and overall dimensions.

Patent application EP 12306128.5 filed on Sep. 18, 2012 but not published yet, discloses a simplified method for producing an electronic device consisting in providing a set of conductive metallizations on a removable substrate, in transferring and then in connecting a microprocessor chip to the set of metallizations, then in over-molding the device body over the chip and the conductive metallizations, so that the conductive metallizations are transferred into the over-molding resin upon separation of the removable substrate.

Document DE 198 19 215 discloses the production of an electronic device wherein an integrated circuit component is connected to pads provided on a substrate and is permanently attached to said substrate. A resin is then deposited onto the component and a main surface disc smaller than the one of the substrate covers the resin which substantially protrudes from the main surface of the reinforcement disc.

However, the applicant has sought to further simplify this method in order to further optimize production costs and further reduce the thickness of the electronic device.

### TECHNICAL PROBLEM

The invention therefore aims at remedying at least one of the disadvantages of the prior art. In particular, the invention aims at providing a method for producing an electronic device that is fast and simple to implement, with a minimum of steps in order to reduce the production costs. The invention also aims at producing electronic devices having small dimensions, and specifically a reduced thickness as compared to existing devices in order to make these compatible with new formats and to facilitate the integration thereof into portable devices.

### SUMMARY OF THE INVENTION

The principle of the invention relies on a specific assembly comprising delivering a protective resin onto the wired chip and transferring, onto the protective resin, a reinforcing disc, the surface of which defines the final contour of the electronic device. This assembly is obtained on a particular substrate where possible contacts or circuit tracks or supply and/or communication interfaces, will be detached from the substrate and transferred into the chip protective resin to form the outer contacts of a microprocessor card for example. For this purpose, the substrate slightly adheres, or adheres in a subsequently alterable way so as to enable the separation thereof.

To this end, the invention relates to a method for producing an electronic device comprising at least one electronic component in a substrate body, with said method comprising at least one step of transferring said electronic component onto a face of a removable dielectric substrate, of delivering a protective resin onto said electronic component, of transferring, onto the protective resin, a reinforcement disc 10 having a main front surface with a peripheral contour,

characterized in that the protective resin extends up to the peripheral contour of the reinforcement disc in order to form, together with the disc, the peripheral side contours and the final layer of the substrate body of the device.

The method of production is thus very simple and makes it possible to eliminate a certain number of conventional steps in the production of microprocessor cards. The steps of injecting the card body or of molding or over-molding the card body in particular, as well as the steps of laminating an adhesive onto the modules strip, then cutting and inserting the electronic module into a cavity of the body card are no longer needed. Similarly, the step of “unplugging or extraction” consisting in detaching a card having a reduced format from a larger card body, such as detaching a SIM card in the 2FF or 3FF or 4FF formats of a card body having a larger format respectively 1FF, 2FF or 3FF, is no longer necessary. With the method according to the invention, the module and the body of the electronic device are made simultaneously with the steps of coating the component(s) and transferring the reinforcement disc. This method further makes it possible to obtain devices having a reduced thickness.

According to other optional characteristics of the method:

the method further comprises, prior to transferring said electronic component, a step of providing and producing at least one set of conductive metallizations on the face of the removable dielectric substrate, with said electronic component being then transferred and electrically connected to said set of conductive metallizations, and in that the protective resin adheres to said set of metallizations with a force greater than the adhesion of the removable dielectric substrate,

subsequently to transferring the disc, the protective resin is set by heat or by exposure to UV radiation,

the removable dielectric substrate is heated to a temperature below the resin polymerization temperature so as to fluidize the latter and to promote the distribution thereof up to the contour of the electronic device,

the method further consists in providing means for stopping the protective resin, said stopping means extending along said final contour of the electronic device and being arranged on the reinforcement disc and/or the removable dielectric substrate,

the stopping means consists of a metal contour etched on the removable substrate, with said metal contour having a width sufficient to make it possible to reach a stronger adhesion of said metal contour on the removable substrate than on the protective resin,

the metal contour etched on the removable substrate is carried out simultaneously to the achievement of the set of metallizations,

the stopping means forms an extra thickness and is formed by addition of material onto the removable dielectric substrate and/or onto the disc,

the removable dielectric substrate is removed from the metallizations and from the protective resin, or destroyed or altered as regards the adhesion thereof in particular by heat,

the removable dielectric substrate comprises a plurality of electronic devices receiving areas and constitutes means for packaging a plurality of electronic devices.

The invention also relates to an electronic device comprising:

at least one electronic component in a substrate body:

a protective material/resin on the electronic component,

a reinforcement disc having a main surface having a peripheral contour positioned on the protective resin,

characterized in that the protective resin extends up to the peripheral contour of the disc with the reinforcement disc in order to form, together with the disc, the peripheral side contours and the final layer of the substrate body of the device.

According to other optional characteristics of the device:

comprises a second face, opposite the first face formed by the reinforcement disc, with said second face being formed and delimited by said protective resin,

the device further comprises a set of metallizations electrically connected to said electronic component, with said set of metallizations being supported by the second face formed by said protective resin,

the outer surface of the metallizations is flush or substantially flush with the outer surface of the protective resin,

the reinforcement disc comprises, along its periphery, an extra thickness, the height of which is equal to the whole or a part of the thickness of the device body,

the thickness of the reinforcement disc ranges from 50 to 300 μm,

the device is obtained with the method described above.

The invention finally relates to a specifically coil substrate comprising a plurality of areas each receiving an electronic device as described above, produced according to the production method disclosed above, with each electronic device being detachable from said substrate by removing the substrate, or destruction or alteration of the adhesion thereof in particular by heat.

### BRIEF DESCRIPTION OF THE FIGURES

Other characteristics and advantages of the invention will become apparent upon reading the following description given by way of illustrative and not restrictive example with reference to the appended Figures which show:

FIGS. 1 to 6, the steps of a method for producing an electronic device according to the invention;

FIGS. 7 to 10, the various methods for separating the removable substrate whereon the electronic device is produced and packaged;

FIG. 11, the various views of electronic devices according to the invention.

### DESCRIPTION

The electronic device according to the invention comprises at least one electronic component connected to a communication interface. The electronic component may for example be in the form of an integrated circuit chip and/or a diode, for example. The communication interface can take different forms depending on the application which the device is intended for. It may for example be in the form of contacts flush with the outer surface of the device, or a coil antenna flush with the surface or embedded in the device body. It may also be in the form of plates, for example acting as a capacitive sensor, embedded in the device body.

When the device comprises a set of metallizations flush with the outer surface thereof, the method comprises a prior step of providing or producing at least one set of metallizations comprising conductive circuit lands or tracks providing a communication and/or supply interface more particularly with electrical contacts and/or a radio frequency antenna, onto an adhesive substrate or having a low adhesiveness.

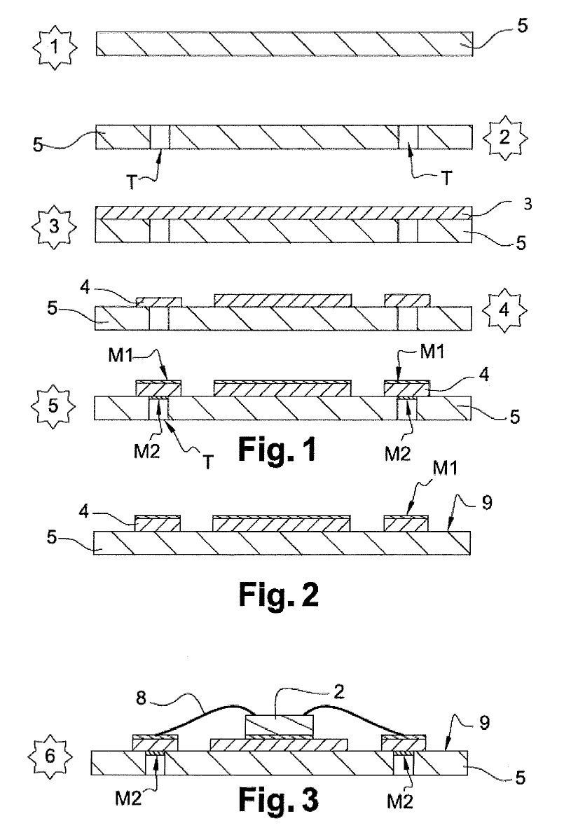

FIG. 1 illustrates the various steps 1 to 5 making it possible to produce at least one metallization 4 set comprising copper contacts on a removable substrate 5, i.e. a detachable substrate. The substrate 5, also called a support in the following description, is a dielectric film chosen for its low adhesion properties, so that the protective resin subsequently provided on its surface can easily be removed. The material such a support can for example be selected from polymers such as PET (polyethylene terephthalate), PEN (polyethylene naphthalate), or a little expensive material like paper.

In the case of an antenna, the latter can be executed as a spiral. The description is preferably made for metallizations with electrical contacts, but the invention may also be applied to other electrically conductive parts such as plates, tracks or antennas, for example. Thus, throughout the description, the contact interface 4 may be replaced by a radio frequency antenna interface.

The support 5 is preferably determined with a plurality of areas each intended for receiving the body of an electronic device. When the device is intended to have surface metallizations, the receiving areas of the substrate 5 are also intended to receive a set of metallizations 4.

If surface metallizations are formed using a method involving current supply tracks, care should be taken that these tracks are few and have a configuration facilitating the separation thereof, during the separation of the electronic devices obtained from the low adhesiveness substrate, for example by having a form of necking or precut or section reduction where they have to be cut-off. They also can be removed by etching or locally cut using laser or any other equivalent method.

A first step 1 thus consists in providing a dielectric 5, preferably coated with a low adhesion adhesive and thus forming the removable substrate 5. The adhesive may be naturally low tack or heat degradable or UV (ultraviolet) degradable or IR (infrared) degradable, so that each set of metallizations 4, in particular made of copper, and the protective resin 7 deposited afterwards on the surface thereof, can be easily detached. The values of low adhesiveness for the metallizations 4 and the protective resin 7 to be easily detached from the substrate 5 may typically range from 0.5 to 5 Newton/cm during the peel strength test at 90 degrees. The peel rate may for example be 30 cm/min or more.

The substrate 5 is then pierced, especially by punching as shown in step 2. The T holes subsequently obtained will make it possible to execute a surface treatment of the metallizations 4. These holes also make it possible to facilitate the separation of the substrate 5 and the removable electronic device obtained.

In step 3, a temporary fixing is carried out, in particular by laminating a conductive foil 3, particularly made of copper, onto the removable dielectric substrate 5. The next step 4 then consists in performing a chemical etching of the conductive foil 3 to achieve the desired shape of the outer contacts 4 for the electronic device being produced.

In step 5, a surface treatment M1, M2 of the copper parts is preferentially made. This treatment of the metallizations 4 consists in adding an additional metallization layer of the Ni/Pd/Au (Nickel/Palladium/Gold) type for example, by forming a passivation layer M1 and/or M2 on the contacts 4. This treatment can be applied to both sides of the etched copper foil. As a matter of fact, the face in contact with the removable substrate 5 may also be surface-treated through the T holes being previously drilled in the removable substrate 5. Thus, the outer contacts 4 intended to be substantially flush with the outer surface of the electronic device, more or less the thickness of the treatment layer M2 or of the adhesive layer of the removable substrate 5, are also treated.

According to an alternative implementation, the removable substrate 5 above may not be punched, as shown in FIG. 2. In this case, the outer contacts 4 may still be made of copper and optionally be protected from oxidation by an organic passivation or any other prior or subsequent surface treatment.

According to another alternative implementation, the substrate above can be punched, as shown in FIG. 1, with a number of T holes greater than those needed for the M2 metallization treatment of the contacts 4, in order to improve the subsequent separation between the removable substrate 5 and the electronic device obtained, since the opposite surface is in fact weaker.

The contact lands 4 may alternately be perforated in order to limit the metallizations and/or enable an electromagnetic permeability if the object also includes an RF antenna, for example etched on the substrate.

If need be, an antenna (not shown) may be provided, for example at the same level as the contacts or conductive tracks, especially at the periphery and/or in a central area with respect to the contacts pads 4.

According to a alternative to the etching operation preferred in the invention, an electrically conductive grid may be set or printed, more particularly by spraying conductive material, onto the removable substrate 5 in order to form electrical contacts 4 and/or tracks and/or at least one antenna.

In step 6 (FIG. 3), an electronic integrated circuit chip 2 is transferred onto the face of the removable substrate 5 comprising the metallizations 4. It may also be directly transferred onto such conductive elements (lands, tracks, antenna turns). The chip 2 is then connected to the metal contacts 4 by wired connections 8 for example. After fixing the chip, especially by bonding, cleaning plasma may be used to improve the adhesion of the protective resin 7, subsequently provided, on the metallized contacts 4. In an alternative embodiment, the electrical connection of the integrated circuit chip 2 with the contacts 4 may also be achieved using the known of “flip chip” or flipped chip technique.

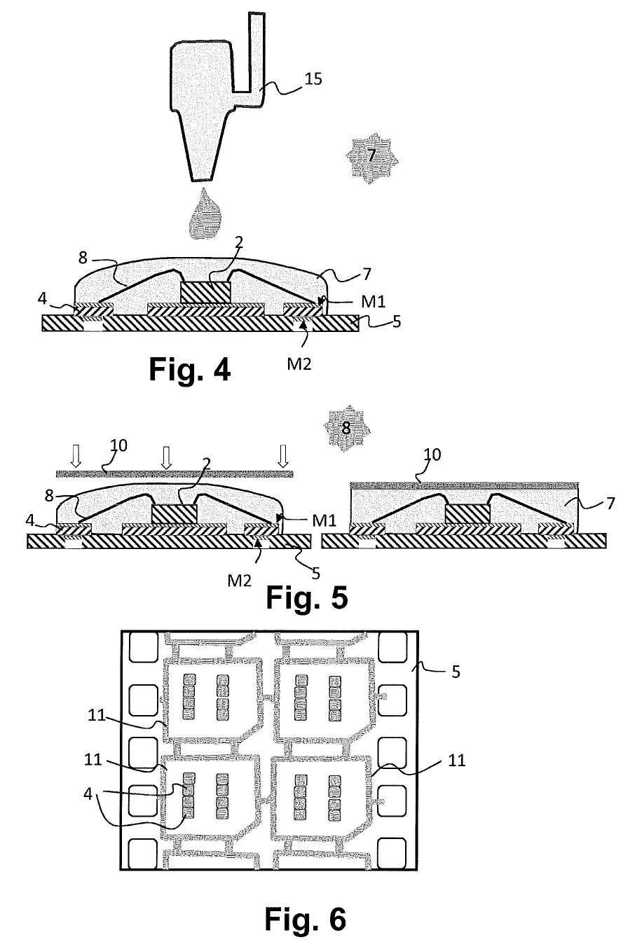

In step 7 (FIG. 4), an insulating protective resin 7 is delivered for coating the chip and the connections 8 thereof (wires), using delivering equipment 15 typically used in the field of microprocessor cards.

A stronger adhesion of the metallizations 4 is preferably provided in contact with the protective resin 7 than in contact with the removable substrate 5. Such adhesion may also be improved using various known methods, such as for instance by increasing the roughness of the contacts 4 copper, by increasing surface roughness (additional metallization M1, M2, of the Ni/Pd/Au type is then adapted to such roughness), by cleaning plasma prior to delivering the protective resin, by anchor points of the protective resin in conductive parts of the metallizations.

In step 8 (FIG. 5), a reinforcement disc 10 cut to the final size of the device is transferred. Such disc has a surface defining the final contour of the electronic device. The reinforcement disc is thus transferred onto the protective resin 7 when the latter is not hardened yet. Such reinforcement disc 10 makes it possible not only to stiffen and mechanically protect the electronic device, but also to obtain a geometrically homogeneous electronic device, in particular having a flat surface. This reinforcement disc is advantageously packaged as a roll and is cut to the final size of the device.

In an alternative embodiment, the disc 10 may also be formed in series by molding for example, and packaged on removable low adhesive substrates, for instance.

The disc is placed on the protective resin using an automatic transfer equipment conventionally used in card producing methods.

The disc may for example have a decoration made by printing, pad printing or any other equivalent method, on the flat surface thereof, in order to form an outer surface opposite the one supporting the metal contacts 4. The surface supporting the metal contacts 4 is also formed by the protective resin 7.

The disc 10 is positioned on top of the connection wires 8. Under the action of the weight of the disc 10, the protective resin 7 is distributed by capillary action up to the contours of the device to form the lateral contours thereof and give it its final thickness.

The nature of the disc may be a composite such as epoxy glass or a thermoplastic polymer such as PET (polyethylene terephthalate), PEN (polyethylene naphthalate), PC (polycarbonate), etc. . . . . The typical thickness of the disc may vary from 50 μm to 300 μm according to its material, the space to be left to the chip and the connections thereof and the desired thickness of the final electronic device.

The protective resin may be a heat polymerizable or UV polymerizable resin. The resin is preferably cured by irradiation with UV radiation. Such resin has indeed interesting advantages. In particular, because of the low heat input of such polymerization, inexpensive removable substrates 5 which cannot take high temperatures may be used. Moreover, the electronic device is not likely to be deformed because of too large differential expansions between the different materials. Finally, UV exposure may be achieved through the disc 10 when the material it is made of is chosen to let the UV wavelengths through, such as through the removable substrate 5 when it is made of a UV transparent material.

The thickness of the resin varies according to the thickness of the final device to be produced and according to the thickness of the reinforcement disc. For a nano-SIM card, again indicated by the 4FF symbol, the thickness of which is normalized to 0.67 mm, for example, the thickness of the resin between the internal surface of the reinforcement disc 10 and the inner surface of the removable substrate 5 will range from 300 to 600 μm.

According to an alternative embodiment, the removable dielectric substrate 5 is heated to a moderate temperature, i.e. to a temperature below the polymerization temperature of resin 7 when the latter is hot-polymerizable, so as to fluidize it and to promote the distribution thereof up to the contour of the electronic device.

The disc may be colored, or even pulp colored. Thus, when the protective resin 7 is transparent, the face around the contacts 4 appears colored.

Optionally, stopping means capable of preventing the creep of the protective resin 7 and the appearance of burrs on the final device may be provided. Said stopping means extends along the contour of the final device and is positioned onto the removable substrate 5 and/or onto the contour of the reinforcement disc 10. Such stopping means is intended to stop the creep of the protective resin, in order to give the final electronic device perfectly straight contours at the time the removable substrate 5 is detached.

On the removable substrate 5 as shown in FIG. 6, the stopping means may be achieved either by metal etching of the contour, or by adding material. Thus, when it is made by metal etching, for example, it may advantageously be in the form of a metal contour etched in the metal foil 3, provisionally fixed to the removable substrate 5, simultaneously with the production of the contacts 4 of the future system electronic removable substrate. Such a metallic etched contour is shown in FIG. 6 as reference 11. In this case, said metal contour is formed sufficiently wide so that the metal constitution more strongly adheres to the removable substrate 5 than to the thin bead of protective resin which may optionally creep on the surface thereof. Thus, when separated from the removable substrate 5, the metal contour 11 and the thin bead of resin having possibly crept on the surface thereof do not delaminate together with the contacts 4 and still adhere to the removable substrate 5.

To further prevent delamination and better prevent the metal contour 11 from being removed with the device upon the detachment thereof, the metallic contour 11 may also be fastened by many current leads that hold it. For the same purpose still, such metallic contour 11 may also be extended over a large part of the removable substrate 5 or even up to the edge thereof. It may also be held by plating a piece against the contour upon detaching the removable substrate 5.

As such metallic contour 11 may have a large area, it will preferably be metallized using the “spot plating” technique which consists in performing electro-deposition in localized areas with reduced and preferential surfaces (selectivity method). Such metal deposition makes it possible to reduce the quantities of metal used and to avoid using precious metals such as gold. The metal contour may for example be made of copper-nickel.

In another alternative embodiment, the stopping means may for example be produced by adding material. This addition of material may be performed on the contour of the face of the disc 10 intended to rest on the protective resin 7, or on the removable substrate along the contour of the final device. This material addition may be achieved by printing material or by delivering an elastomeric material such as silicone for instance. It thus forms a rim or an extra thickness.

The stopping means may also be an integral part of the disc 10 when the latter is obtained using a molding technique, for instance.

In this case, the height of the stopping means, or rim, is equal to the whole or a part of the final thickness of the device.

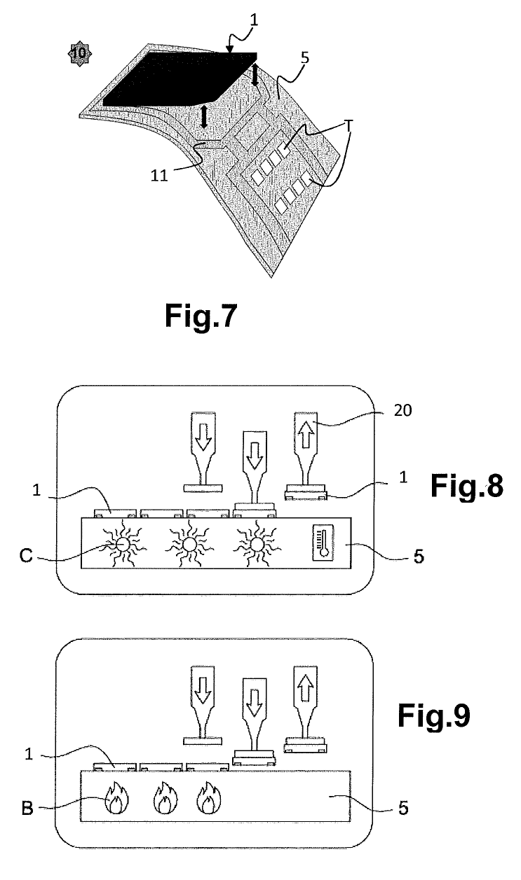

In step 10 (FIG. 7), a separation of the obtained electronic device 1, the contacts 4 of which adhere to the protective resin 7, from the removable substrate 5 is executed. Such separation may be achieved in different ways.

The substrate 5 is preferably determined with a plurality of devices receiving areas for providing a plurality of devices in series, which are packaged on the removable substrate 5, which may itself be coiled, for instance. Upon separating the removable substrate 5, the electronic device 1 is detached and only the previously punched T holes remain on the substrate 5 and the stopping means 11 of the resin optionally formed along the outer periphery of the device 1.

The devices can then be seized, on such a substrate 5, especially using suckers (FIG. 8) positioned on mobile robotic grippers 20 after heating “C” the substrate 5, in particular using infrared lamps, in order to degrade the adhesion of the adhesive provisionally holding the devices 1 on the substrate 5 and thus enable the separation of the device 1 with its set of metallizations (contacts, tracks), relative to the substrate 5. The adhesive may be a thermoplastic or hot-melt adhesive.

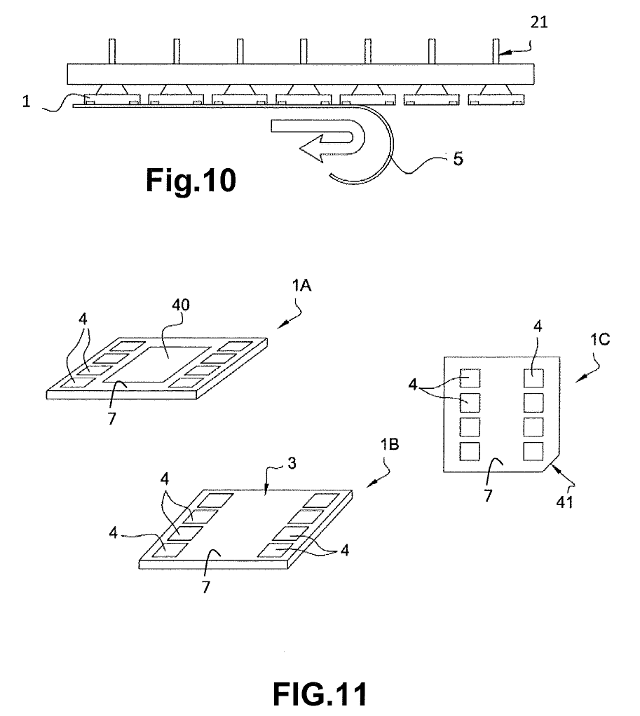

In an alternative solution (FIG. 9) the substrate may be destroyed in particular by burning “B” as in the case of a paper substrate 5 for instance. The individual devices may also be peeled off from the substrate 5 (FIG. 10), with the packages being held by suction on nozzles 21.

In FIG. 11, the electronic devices 1A to 1C obtained here have the form of electrical contacts 4 mini cards 1A, 1B, 1C flush with the main surface thereof. The protective resin 7 constituting the insulating body of the mini-card comprises a face 3 which may be at the same level as the contact lands 4. In other words, the various metallizations 4 are spaced apart by insulating material, i.e. the protective resin 7, and are substantially flush with the outer face 3 of the device formed by the protective resin 7. Where applicable, depending on the alternative surface treatments, the level may be slightly different between the metallizations 4 and the protective resin 7. As a matter of fact, if the removable substrate 5 contains or not an adhesive layer, the surface treatment metallization layer M2 located in the T hole of the removable substrate 5, which is distinct from the substrate metallization 4 may have a level higher than the level of the outer face 3 of the protective resin 7. According to the deposited thickness of the treatment metallization M2, the contact lands 4 of the device 1 may be flush with the main surface 3 of the protective resin 7, by a value ranging from 0 μm to preferably 25 μm or even 50 μm.

The object 1A may comprise, in the center thereof, an area 40 for any king of metallization (contact, antenna . . . ). The object 1B is a parallelepiped and the object 1C includes a polarizing notch 41 in addition to the previous one.

Thanks to the invention, electrical/electronic components or metallizations 4 of the electronic device may be arranged prior to the step of coating, so that the outer surface of the components is at the same level or substantially at the same level as the outer surface 3 of the protective resin 7 delivered at the step of coating.

Thanks to the invention the thickness of the electronic devices can be minimized. The chip may be placed directly on one of the metallizations 4 or directly on the removable substrate 5. The number of stacked elements composing the electronic device is reduced. In particular, the electronic devices produced according to the invention no longer comprise a dielectric substrate film in the final constitution thereof. The steps of the method are fewer, the steps of over-molding a device body being specifically eliminated. Transferring the chip 10 in the final format of the electronic device onto the protective resin 7 makes it possible to encapsulate the chip and its connections, and to produce the body of the final electronic device in one step.

In another alternative solution relating to the fixing of the chip, the latter may be glued directly onto the face 9 of the removable low tack substrate 5, unlike in FIG. 3. Thus, after removing the substrate 5, the adhesive fixing the chip is flush with the outer face 3 of the protective resin 7 of the electronic device 1, or substantially at the same level as the metallizations 4.

In another alternative solution, the reduction in the thickness of the device may even reach a minimum by placing the chip 2 directly on the low tack substrate 5 or a substrate 5 coated with an adhesive described above. After removing the substrate 5, the rear face of the chip 2 is thus positioned on the surface 3 of the electronic device 1.

Where appropriate, an electronic component such as a fingerprint sensor may be at the surface of the face 3 of the electronic device because it has been mounted directly against the surface 9 of the removable substrate 5 like the chip 2. A component, such as an electronic chip or element acting as a fingerprint sensor, may thus be mounted so as to provide a flat surface flush with the outer surface 3 of the electronic device.

The present invention also makes it possible to reduce the thickness of the SIM cards if needed, since only the useful contacts or metallizations will be retained, after transferring these into the protective resin and separating the removable substrate thickness. Besides, the contacts are integrated in the protective resin and have very little or no extra thickness. The method for producing electronic devices according to the invention has a reduced number of steps, which results in a reduction in cost.

1. A method for producing an electronic device comprising at least one electronic component in a substrate body, with said method comprising at least the steps of:
transferring said electronic component to a face of a removable dielectric substrate,
delivering a protective resin on said electronic component,
transferring, onto the protective resin/material, a reinforcement disc having a main surface with a peripheral contour,
wherein the protective resin extends up to the peripheral contour of the disc in order to form, together with the disc, the peripheral side contours and the final thickness of the substrate body of the device.

2. A production method according to claim 1, wherein the method further comprises, prior to transferring said electronic component, a step of providing and producing at least one set of conductive metallizations on the face of the removable dielectric substrate, with said electronic component being then transferred and electrically connected to said set of conductive metallizations, and wherein the protective resin adheres to said set of metallizations with a force greater than the adhesion of the removable dielectric substrate.

3. A method according to claim 1, wherein, subsequently to transferring the disc, the protective resin is set by heat or by exposure to UV radiation.

4. A method according to claim 1, wherein the removable dielectric substrate is heated to a temperature below the resin polymerization temperature so as to fluidize the latter and to promote the distribution thereof up to the contour of the electronic device.

5. A method according to claim 1, further comprising providing means for stopping the protective resin, with said stopping means extending along said final contour of the electronic device and being arranged on the reinforcement disc and/or the removable dielectric substrate.

6. A method according to claim 5, wherein the stopping means comprises a metal contour etched on the removable substrate, with said metal contour having a width sufficient to make it possible to obtain a stronger adhesion of said metal contour on the removable substrate than on the protective resin.

7. A method according to claim 6, wherein the metal contour etched on the removable substrate is carried out simultaneously to the achievement of the set of metallizations.

8. A method according to claim 5, wherein the stopping means forms an extra thickness and is formed by addition of material on the removable dielectric substrate and/or on the disc.

9. A method according to claim 2, wherein the removable dielectric substrate is removed from the metallizations and from the protective resin, or destroyed or altered as regards the adhesion thereof by heat.

10. A method according to claim 1, wherein the removable dielectric substrate comprises a plurality of electronic devices receiving areas and constitutes means for packaging a plurality of electronic devices.

11. An electronic device comprising:
at least one electronic component in a substrate body:
a protective resin on the electronic component,
a reinforcement disc having a main surface having a peripheral contour positioned on the protective resin,
wherein the protective resin extends up to the peripheral contour of the disc with the reinforcement disc in order to form, together with the disc, the peripheral side contours and the final thickness of the substrate body of the device.

12. An electronic device according to claim 11, further comprising a second face, opposite the first face formed by the reinforcement disc, with said second face being formed and delimited by said protective resin.

13. An electronic device according to claim 12, further comprising a set of metallizations electrically connected to said electronic component, with said set of metallizations being supported by the second face formed by said protective resin.

14. An electronic device according to claim 13, wherein the outer surface of the metallizations is flush or substantially flush with the outer surface of the protective resin.

15. An electronic device according to claim 11, wherein the reinforcement disc comprises, along its periphery, an extra thickness, the height of which is equal to the whole or a part of the thickness of the device body.

16. An electronic device according to claim 11, wherein the thickness of the reinforcement disc ranges from 50 to 300 μm.

17. An electronic device that is obtained with the method according to claim 1.

18. A specifically coil substrate comprising a plurality of areas each receiving an electronic device having at least one electronic component in a substrate body, a protective resin on the electronic component, and a reinforcement disc having a main surface with a peripheral contour positioned on the protective resin, produced according to the production method of claim 1, wherein each electronic device can be detached from said substrate by removing the substrate, or destruction or alteration of the adhesion thereof by heat.
